(19) United States
(12) Patent Application Publication
(10) Pub. No.: US 2007/0251573 A1
(43) Pub. Date: Nov. 1, 2007

(54) Photoelectric Converter

(76) Inventors: Takashi Suezaki, Moriyama-shi (JP); Kenji Yamamoto, Kobe-shi (JP)

Correspondence Address: BIRCH STEWART KOLASCH & BIRCH, PO BOX 747, FALLS CHURCH, VA, 22040-0747, US

(21) Appl. No.: 11/664,529

(22) PCT Filed: Sep. 20, 2005
(86) PCT No.: PCT/JP05/17296

§ 371 Date: Apr. 3, 2007

(30) Foreign Application Priority Data
Oct. 4, 2004 (JP) 2004-291830

(51) Int. Cl. H01L 31/00

(52) U.S. Cl. 136/258

(57) ABSTRACT

It is intended to provide a highly reliable photoelectric converter having a reflective layer, deterioration in output characteristics thereof being suppressed under a constant temperature and humidity environment. The photoelectric converter according to the present invention has at least one thin film silicon-based photoelectric conversion unit mainly composed of a silicon-based thin film including at least one semiconductor junction, characterized in that the photoelectric converter has a silicon alloy layer containing a kind of dopant for determining a conductivity type, oxygen, nitrogen, and crystalline silicon on a side opposite to a light incident side of the thin film silicon-based photoelectric conversion unit, and that the silicon alloy layer has a refractive index of at most 2.5 and a nitrogen concentration in a range of 1×10²¹ atom/cc to 1 to 10²² atom/cc.

### TECHNICAL FIELD

The present invention relates to improvement in reliability of a photoelectric converter.

### BACKGROUND ART

These days a variety of photoelectric converters have been produced, and there have been developed a thin film photoelectric converter using thin film material as well as a crystal-type photoelectric converter using monocrystalline or polycrystalline silicon. As examples of the thin film photoelectric converters, there are an amorphous silicon photoelectric converter including an amorphous silicon photoelectric conversion unit and a crystalline silicon photoelectric converter including a crystalline silicon photoelectric conversion unit (which are collectively referred to as a thin film silicon-based photoelectric converter including a thin film silicon-based photoelectric conversion unit), and then a multiple junction type of thin film silicon-based photoelectric converter including these units stacked therein has also been put in practical use. It should be noted that the term “crystalline” used herein includes meanings of “polycrystalline” and “microcrystalline” and that the terms “crystalline” and “microcrystalline” include a meaning of a partially amorphous state also.

In general, a thin film photoelectric converter includes a transparent electrode film, at least one thin film photoelectric conversion unit, and a back electrode film successively stacked on a base made of a glass plate, a resin film, or the like. A thin film photoelectric conversion unit contains semiconductor junctions between semiconductors and includes an i-type layer sandwiched between a p-type layer and an n-type layer.

The i-type layer that occupies a major part of the thickness of the thin film photoelectric conversion unit is a substantially intrinsic semiconductor layer and referred to as a photoelectric conversion layer, because photoelectric conversion effect is mainly caused in this i-type layer. The i-type layer preferably has a larger thickness for the purpose of increasing light absorption and then photocurrent.

In contrast, the p-type and n-type layers are referred to as conductive-type layers and serve to cause a diffusion potential in the thin film photoelectric conversion unit. The magnitude of the diffusion potential influences the value of the open-circuit voltage (Voc) that is one of the characteristics of the thin film photoelectric converter. However, these conductive-type layers are non-active layers that do not directly contribute to photoelectric conversion. Accordingly, light absorbed by dopant impurities contained in the conductive-type layers does not contribute to electric power generation, resulting in a loss. Furthermore, when the conductive-type layers have lower electrical conductivity, the thin film photoelectric converter has higher electrical series resistance and thus comes to have lowered photoelectric conversion characteristics. Therefore, the p-type and n-type conductive layers preferably have their high electrical conductivity and also their thickness as small as possible, as long as they can cause a sufficient diffusion potential.

As such, the thin film photoelectric conversion units or converter is referred to as an amorphous silicon photoelectric conversion unit or converter when the i-type layer that occupies a main part thereof is formed of amorphous silicon material, and is referred to as a crystalline silicon photoelectric conversion unit or converter when the i-type layer is formed of crystalline silicon material, regardless of whether the conductive-type layers included therein are formed of amorphous or crystalline material.

In a method of improving conversion efficiency of a thin film silicon-based photoelectric converter, a reflective transparent layer is provided on a side opposite to a light incident side of a thin film silicon-based photoelectric conversion unit in the photoelectric converter, to cause optical confinement and increase photocurrent in the photoelectric conversion unit. In the case of a multiple junction type of thin film silicon-based photoelectric converter, a reflective transparent layer in a photoelectric conversion unit placed farthest from the light incident side is particularly referred to as a back reflective layer, and the other reflective transparent layer(s) in the other photoelectric conversion unit(s) is particularly referred to as an intermediate reflective layer(s).

Patent Document 1 discloses such a back reflective layer and an intermediate reflective layer that contain silicon oxide. Patent Document 2 discloses that a silicon oxide semiconductor layer of a low refractive index is used as an intermediate reflective layer. As disclosed in the prior art documents, silicon oxide (including silica, silicon monoxide, etc.) is hopeful material for a reflective layer of a thin film silicon-based photoelectric converter, from the viewpoint of its physical properties and a method of forming the layer.

A photoelectric converter for power use is exposed outdoors for a long period of time, and thus it is important for it to have stability in characteristics (hereinafter referred to as reliability) over the long period of time. As a methodology of evaluating the reliability, there is widely carried out an accelerated test under a constant temperature and humidity environment. A thin film silicon-based photoelectric converter including the above-described silicon oxide layer as a reflective layer was subjected to an accelerated test under a constant temperature and humidity environment based on the Japanese Industrial Standards (JIS), and it was revealed as a result that this photoelectric converter is slightly inferior in reliability as compared to a thin film silicon-based photoelectric converter not including the silicon oxide layer. Specifically, it was revealed that the photoelectric converter including the silicon oxide layer deteriorates in characteristics with a shorter period of time in the accelerated test and particularly shows significant decrease in fill factor (F. F.) owing to increase in series resistance component. It seems that this is mainly because resistance of the silicon oxide layer is increased under the constant temperature and humidity environment.

Patent Document 1: Japanese Patent Laying-Open No. 2003-298088

Patent Document 2: Japanese Patent Laying-Open No. 2003-258279

### DISCLOSURE OF THE INVENTION

Problems to be Solved by the Invention

In view of the above-described circumstances, an object of the present invention is to improve reliability of a photoelectric converter including a reflective layer.

Means for Solving the Problems

A photoelectric converter according to the present invention includes at least one thin film silicon-based photoelectric conversion unit mainly composed of a silicon-based thin film containing at least one semiconductor junction, and also includes a silicon alloy layer containing a kind of dopant for determining a conductivity type, oxygen, nitrogen, and crystalline silicon on a side opposite to a light incident side of the photoelectric conversion unit, wherein the silicon alloy layer has a refractive index of at most 2.5 and a nitrogen content in a range of 1×10²¹ atoms/cc to 1×10²² atoms/cc.

By using the silicon alloy layer containing crystalline silicon and substantial nitrogen instead of a silicon alloy layer containing crystalline silicon but not substantial nitrogen as a reflective layer of a photoelectric converter, it is possible to suppress increase in resistance of the reflective layer under a constant temperature and humidity environment and accordingly it becomes possible to improve reliability of the photoelectric converter.

Effects of the Invention

The photoelectric converter according to the present invention includes at least one thin film silicon-based photoelectric conversion unit mainly composed of a silicon-based thin film containing at least one semiconductor junction, and also includes a silicon alloy layer containing a kind of dopant for determining a conductivity type, oxygen, nitrogen, and crystalline silicon on a side opposite to a light incident side of the photoelectric conversion unit. By using the silicon alloy layer, it is possible to improve reliability of the photoelectric converter owing to suppression of increase in resistance of the reflective layer under a constant temperature and humidity environment.

### BRIEF DESCRIPTION OF THE DRAWINGS

FIG. 1 is a cross section schematically showing a double junction type of thin film silicon-based photoelectric converter.

FIG. 2 is a graph for comparing characteristics of Example 1 and Comparative Example 1 under a constant temperature and humidity environment.

FIG. 3 is a graph for comparing characteristics of Example 2 and Comparative Example 2 under a constant temperature and humidity environment.

FIG. 4 is a graph for comparing characteristics of Example 3 and Comparative Example 3 under a constant temperature and humidity environment.

Description of the Reference Signs

1 base, 2 transparent electrode film, 3a amorphous silicon photoelectric conversion unit, 3b crystalline silicon photoelectric conversion unit, 4a intermediate reflective layer, 4b back reflective layer, 5 back electrode film, 6 sealing resin layer, 7 organic protective layer.

### BEST MODES FOR CARRYING OUT THE INVENTION

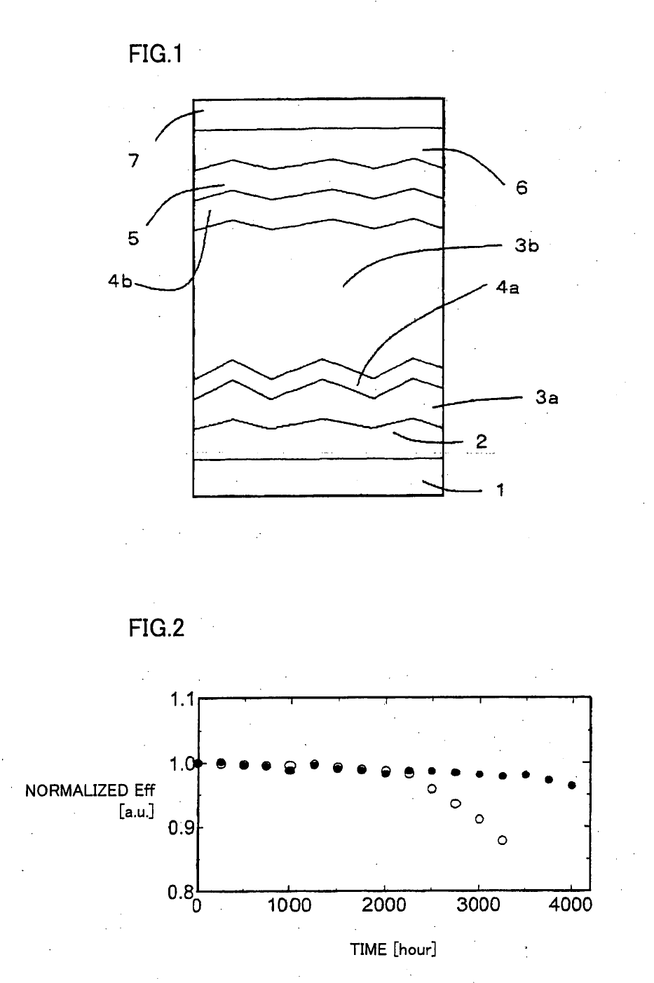

As a photoelectric converter according to an embodiment of the present invention, FIG. 1 shows a schematic cross section of a double junction type of thin film silicon-based photoelectric converter. The present invention will hereinafter be described in detail with reference to FIG. 1, but the present invention is not limited thereto.

Each component in the double junction type of thin film silicon-based photoelectric converter according to the present invention will be described below.

For a base 1, it is possible to use a glass plate, a transparent resin film, or the like. As the glass plate, it is possible to use a soda-lime glass plate mainly composed of SiO₂, Na₂O and CaO, which has a pair of smooth main surfaces, a high transparency, and a high insulating property. Such a soda-lime glass plate having a large area is available at a low cost.

A transparent electrode film 2 can include a transparent conductive oxide layer such as an ITO film, an SnO₂ film, or a ZnO film. Transparent electrode film 2 may have a single-layer structure or a multilayer structure. Transparent electrode film 2 can be formed by a vapor deposition method well known per se, such as an evaporation method, a CVD method, or a sputtering method. It is preferable to form a textured surface structure including fine unevenness on a surface of transparent electrode film 2. In the surface unevenness, the level difference is preferably in a range of 0.05 μm to 1.0 μm and the spacing between peaks is preferably in a range of 0.05 μm to 1.0 μm. By forming such a textured structure on the surface of transparent electrode film 2, it is possible to increase the optical confinement effect.

The double junction type of thin film silicon-based photoelectric converter according to the present invention shown in FIG. 1 includes an amorphous silicon photoelectric conversion unit 3a and a crystalline silicon photoelectric conversion unit 3b, together with an intermediate reflective layer 4a and a back reflective layer 4b provided on the backs of amorphous unit 3a and crystalline unit 3b, respectively. Each of intermediate reflective layer 4a and back reflective layer 4b is made of a silicon alloy layer containing a kind of dopant for determining a conductivity type, oxygen, nitrogen, and crystalline silicon, which is an important feature of the present invention.

Amorphous silicon photoelectric conversion unit 3a includes an amorphous silicon photoelectric conversion layer, and has a structure in which a p-type layer, the amorphous silicon photoelectric conversion layer, and an n-type layer are successively stacked from the side of transparent electrode film 2. All of the p-type layer, the amorphous silicon photoelectric conversion layer, and the n-type layer can be formed by a plasma CVD method.

On the other hand, crystalline silicon photoelectric conversion unit 3b includes a crystalline silicon photoelectric conversion layer, and has a structure in which a p-type layer, the crystalline silicon photoelectric conversion layer, and an n-type layer are successively stacked from the side of intermediate reflective layer 4a. All of the p-type layer, the crystalline silicon photoelectric conversion layer, and the n-type layer can also be formed by a plasma CVD method.

The p-type layer, which is included in each of these thin film silicon-based photoelectric conversion units 3a and 3b, can be formed with silicon or a silicon alloy such as silicon carbide, silicon oxide, silicon germanium, or the like doped with impurity atoms such as of boron or aluminum for the p conductivity type. The amorphous silicon photoelectric conversion layer and the crystalline silicon photoelectric conversion layer can be formed of an amorphous silicon-based semiconductor material and a crystalline silicon-based semiconductor material, respectively. As such materials, it is possible to use an intrinsic semiconductor of silicon (e.g., hydrogenated silicon), a silicon alloy such as silicon carbide or silicon germanium, and the like. It is also possible to use a weak p-type or weak n-type silicon-based semiconductor material containing a slight amount of impurities determining the conductivity type, as long as the material achieves a sufficient photoelectric conversion function. Furthermore, the n-type layer can be formed with silicon or a silicon alloy such as silicon carbide, silicon oxide, silicon germanium, or the like doped with impurity atoms such as of phosphorus or nitrogen for the n conductivity type.

Amorphous silicon photoelectric conversion unit 3a and crystalline silicon photoelectric conversion unit 3b formed as above have absorption wavelength ranges different from each other. The photoelectric conversion layer in amorphous silicon photoelectric conversion unit 3a is formed with amorphous silicon, while the photoelectric conversion layer in crystalline silicon photoelectric conversion unit 3b is formed with crystalline silicon, and hence it is possible to make the former most efficiently absorb a light component of approximately 550 nm wavelength, and make the latter most efficiently absorb a light component of approximately 800 nm wavelength.

The thickness of amorphous silicon photoelectric conversion unit 3a is preferably in a range of 0.01 μm-0.5 μm, and more preferably in a range of 0.1 μm-0.3 μm.

On the other hand, the thickness of crystalline silicon photoelectric conversion unit 3b is preferably in a range of 0.1 μm-10 μm, and more preferably in a range of 0.1 μm-5 μm.

Each of intermediate reflective layer 4a and back reflective layer 4b is made of a silicon alloy layer containing a kind of dopant for determining a conductivity type, oxygen, nitrogen, and crystalline silicon, which is an important feature of the present invention. The dopant can be boron, aluminum, phosphorus, or the like. Presence of crystalline silicon can be confirmed by Raman scattering spectroscopy for observing a peak in a wave number range of 500 cm⁻¹-520 cm⁻¹ caused by crystalline silicon TO phonons. Intermediate reflective layer 4a and back reflective layer 4b can be formed by a plasma CVD method while base 1 is maintained at a temperature of at most 300° C.

Each of intermediate reflective layer 4a and back reflective layer 4b has a refractive index of at most 2.5 and preferably at most 2.0 with respect to light having a wavelength of 600 nm. If the refractive index is more than 2.5, it is not possible to obtain sufficient reflection, and hence not possible to obtain a sufficient optical confinement effect. The refractive index can be measured as follows. A silicon alloy layer containing a kind of dopant for determining a conductivity type, oxygen, nitrogen, and crystalline silicon is formed to have a thickness of approximately 0.1-0.4 μm on a transparent insulating base such as a glass substrate, under a condition similar to that used in forming intermediate reflective layer 4a or back reflective layer 4b, and the refractive index of the formed layer is measured by spectroellipsometry. At the same time, it is also possible to determine the film thickness. The silicon alloy layer formed at this time has an electrical conductivity of at least 1.0×10⁻⁹ S/cm. The electrical conductivity can be measured as follows. A pair of aluminum electrodes each having an area of 1 mm×15 mm and spaced by 1 mm from each other are formed by a vacuum evaporation method on the silicon alloy layer formed having a thickness of approximately 0.1-0.4 μm, and a voltage of 100 V is applied between these electrodes to obtain a current value from which the electrical conductivity can be calculated. For the thickness value of the silicon alloy layer, which is needed for the calculation, it is possible to use the thickness value obtained by spectroellipsometry. If the electrical conductivity is smaller than 1.0×10⁻⁹ S/cm, the series resistance becomes high and the conversion efficiency becomes low.

Furthermore, each of intermediate reflective layer 4a and back reflective layer 4b has a nitrogen content in a range of 1×10²¹ atom/cc to 1×10²² atom/cc. The nitrogen content value can be determined by secondary ion mass spectroscopy. If the nitrogen content is smaller than 1×10²¹ atom/cc, there cannot be expected a sufficient effect of improving the reliability. If the nitrogen content is larger than 1×10²² atom/cc, the electrical conductivity is decreased and the series resistance is increased, which causes deterioration in the conversion efficiency.

A back electrode film 5 not only serves as an electrode but also serves as a reflective layer. Light having entered from base 1 and passed through thin film photoelectric conversion units 3a and 3b is reflected back to those units 3b and 3a by back electrode film 5. Back electrode film 5 can be formed with silver, aluminum or the like by an evaporation method or a sputtering method to have a thickness of approximately 200 nm-400 nm, for example.

A transparent conductive thin film (not shown) made of a non-metal material such as ZnO may be provided between back electrode film 5 and thin film photoelectric conversion unit 3b to improve, for example, adhesion therebetween.

Furthermore, in order to perform an environmental test under a constant temperature and humidity environment, the back face of the photoelectric converter is sealed with an organic protective layer 7 with a sealing resin layer 6 interposed therebetween. For sealing resin layer 6, there is used a resin that can bond organic protective layer 7 to the photoelectric converter. As such a resin, it is possible to use, for example, ethylene-vinyl acetate copolymer (EVA), polyvinyl butyral (PVB), polyisobutylene (PIB), a silicone resin, or the like. For organic protective layer 7, there is used a fluororesin-based film such as a polyvinyl fluoride film (e.g., Tedlar (registered trademark) film) or an insulating film such as a PET film excellent in moisture resistance or water resistance. Organic protective layer 7 may have a single-layer structure or a multilayer structure in which a plurality of single-layer structures are stacked. Furthermore, organic protective layer 7 may have a structure in which a metal foil made of aluminum, for example, is sandwiched between the organic films. The metal foil such as an aluminum foil has a function of improving moisture resistance or water resistance, and hence organic protective layer 7 having such a structure can effectively protect the photoelectric converter from moisture. These sealing resin layer 6/organic protective layer 7 can be applied simultaneously to the back face side of the photoelectric converter by a vacuum laminating method.

### EXAMPLES

The present invention will hereinafter be described in detail, based on some examples and comparative examples. However, the present invention is not limited to the examples described below, as long as it does not exceed the gist thereof.

### Example 1

As Example 1, there was fabricated a double junction type of thin film silicon-based photoelectric converter having amorphous silicon photoelectric conversion unit 3a and crystalline silicon photoelectric conversion unit 3b shown in FIG. 1.

On glass substrate 1 having a thickness of 0.7 mm, ZnO film 2 of 1 μm thickness with surface unevenness was formed as transparent electrode film 2 by a CVD method. In the surface unevenness at this time, the level difference is in a range of 0.1 μm to 0.5 μm, and the spacing between peaks is in a range of 0.1 μm to 0.5 μm. On transparent electrode film 2, a p-type layer of 15 nm thickness was formed by introducing silane, hydrogen, methane, and diborane as reactive gases, and an amorphous silicon photoelectric conversion layer of 300 nm thickness was then formed by introducing silane as a reactive gas, and further an n-type layer of 10 nm thickness was formed by introducing silane, hydrogen, and phosphine as reactive gases, to thereby form amorphous silicon photoelectric conversion unit 3a. After formation of amorphous silicon photoelectric conversion unit 3a, intermediate reflective layer 4a of 60 nm thickness was formed by introducing silane, hydrogen, phosphine, carbon dioxide, and ammonia as reactive gases. Subsequently, a p-type layer of 10 nm thickness was formed by introducing silane, hydrogen, and diborane as reactive gases, and a crystalline silicon photoelectric conversion layer of 2.5 μm thickness was then formed by introducing hydrogen and silane as reactive gases, and further an n-type layer of 5 nm thickness was formed by introducing silane, hydrogen, and phosphine as reactive gases, to thereby form crystalline silicon photoelectric conversion unit 3b. After formation of crystalline silicon photoelectric conversion unit 3b, back reflective layer 4b of 60 nm thickness was formed by introducing silane, hydrogen, phosphine, carbon dioxide, and ammonia as reactive gases. All of amorphous silicon photoelectric conversion unit 3a, crystalline silicon photoelectric conversion unit 3b, intermediate reflective layer 4a, and back reflective layer 4b were formed by a plasma CVD method.

Subsequently, a ZnO film of 30 nm thickness was formed by a sputtering method to improve adhesion to back face electrode 5, and then Ag film 5 was formed as back face electrode 5 by a sputtering method as well.

Subsequently, an EVA sheet serving as sealing resin layer 6 was placed on the back face side of the double junction type of thin film silicon-based photoelectric converter, and a black fluororesin-based sheet (trademark: Tedlar) serving as organic protective layer 7 was placed thereon. The double junction type of thin film silicon-based photoelectric converter was laminated with these sheets by a vacuum laminating method, and hence sealed therewith.

Condition A in Table 1 shows the gas flow rate condition for formation of intermediate reflective layer 4a and back reflective layer 4b at this time. The refractive index, electrical conductivity, and nitrogen content of intermediate reflective layer 4a and back reflective layer 4b under condition A were measured as follows. A silicon alloy layer formed on glass substrate 1 under condition A of Table 1 was measured by spectroellipsometry, so that there were obtained a refractive index value of 1.95 with respect to light of 600 nm wavelength and a film thickness value of 189 nm. Subsequently, a pair of aluminum electrodes each having an area of 1 mm×15 mm and spaced by 1 mm from each other were formed on the silicon alloy layer by a vacuum evaporation method, and a voltage of 100 V was applied between these electrodes to measure a current value. The obtained current value was 2.44×10⁻⁵ A, from which there was calculated an electrical conductivity of 8.63×10⁻⁴ S/cm. When the nitrogen concentration in the silicon alloy layer was measured by secondary ion mass spectroscopy, it was in a range of 2.7×10²¹ atom/cc to 3.0×10²¹ atom/cc and no remarkable concentration distribution was observed in the depth direction. Furthermore, when the silicon alloy layer was measured by Raman scattering spectroscopy, a peak was observed at a wave number of 511 cm⁻¹, so that the silicon alloy layer was found to contain crystalline silicon.

TABLE 1
All the values are expressed in the unit of sccm.

| | | | Hydrogen | | Hydrogen |
|---|---|---|---|---|---|
| | | | Diluted | | Diluted |
| | | | Phosphine | Carbon | Ammonia |
| | Hydrogen | Silane | (0.5%) | Dioxide | (10%) |
| Condition A | 2000 | 5 | 60 | 20 | 10 |
| Condition B | 2000 | 5 | 60 | 20 | 0 |

The double junction type of thin film silicon-based photoelectric converter obtained as above was irradiated with light of AM 1.5 at a light intensity of 100 mW/cm² to measure its output characteristics. As listed under the field of 0 hour in Table 2, Example 1 showed an open-circuit voltage (Voc) of 1.38 V, a short-circuit current density (Jsc) of 13.8 mA/cm², a fill factor (F. F.) of 72.2%, and conversion efficiency (Eff) of 13.8%, as output characteristics per unit area of 1 cm².

TABLE 2

| | 0 Hour | | | | 3000 Hours | | | |
|---|---|---|---|---|---|---|---|---|
| | | Jsc | | | | Jsc | | |
| | Vcc | [mA/ | F.F. | Eff | Vcc | [mA/ | F.F. | Eff |
| | [V] | cm²] | [%] | [%] | [V] | cm²] | [%] | [%] |
| Example 1 | 1.38 | 13.8 | 72.2 | 13.8 | 1.37 | 13.9 | 71.6 | 13.5 |
| Comparative | 1.37 | 13.6 | 73.2 | 13.7 | 1.36 | 13.7 | 66.8 | 12.5 |
| Example 1 | | | | | | | | |
| Example 2 | 1.39 | 11.7 | 73.4 | 11.9 | 1.39 | 11.7 | 72.2 | 11.8 |
| Comparative | 1.40 | 11.6 | 74.3 | 12.0 | 1.39 | 11.7 | 68.3 | 11.1 |
| Example 2 | | | | | | | | |
| Example 3 | 1.38 | 12.8 | 74.3 | 13.1 | 1.37 | 12.8 | 73.5 | 12.9 |
| Comparative | 1.38 | 12.9 | 74.4 | 13.2 | 1.38 | 12.9 | 70.2 | 12.6 |
| Example 3 | | | | | | | | |

Next, in order to perform a reliability test on the double junction type of thin film silicon-based photoelectric converter, this converter in its open-circuit state was left in an air at an atmospheric pressure in an oven maintained at a temperature of 85° C. and at a relative humidity (RH) of 85%, based on the JIS. After it was left for 250 hours, its output characteristics were measured again in the same method as the above-described method, and such measurement was repeated. The results are shown by black dots in FIG. 2. It is noted that FIG. 2 shows the conversion efficiency (Eff) normalized with respect to the Effat 0 hour. As shown under the field of 3000 hours in Table 2, Example 1 showed an open-circuit voltage (Voc) of 1.39 V, a short-circuit current density (Jsc) of 13.9 mA/cm², a fill factor (F. F.) of 71.6%, and conversion efficiency (Eff) of 13.5%, as output characteristics after 3000 hours.

### Comparative Example 1

In a similar structure as in Example 1, intermediate reflective layer 4a and back reflective layer 4b were formed by introducing silane, hydrogen, phosphine, and carbon dioxide as reactive gases, as shown in condition B of Table 1. When the refractive index, electrical conductivity, and nitrogen content of intermediate reflective layer 4a and back reflective layer 4b formed under condition B were measured by the same method as in Example 1, there were obtained a refractive index of 1.99 with respect to light of 600 nm wavelength, an electrical conductivity of 2.37×10⁻⁴ S/cm, and a carbon concentration in a range of 6.5×10¹⁹ atom/cc to 3.0×10²⁰ atom/cc. Furthermore, when the silicon alloy layer was measured by Raman scattering spectroscopy, a peak was observed at a wave number of 514 cm⁻¹, and hence the silicon alloy layer was found to contain crystalline silicon. When output characteristics were measured similarly as in Example 1, Comparative Example 1 showed an open-circuit voltage (Voc) of 1.37 V, a short-circuit current density (Jsc) of 13.6 mA/cm², a fill factor (F. F.) of 73.2%, and conversion efficiency (Eff) of 13.7%, as listed under the field of 0 hour in Table 2. Regarding the reliability, the conversion efficiency (Eff) of Comparative Example 1 was lowered earlier as compared to Example 1, as shown by white dots in FIG. 2, where the white dots indicate the results of the same reliability tests performed on Comparative Example 1 as the tests in Example 1. It is noted that, similarly as in the case of the black dots, the white dots also show the conversion efficiency (Eff) normalized with respect to the Eff at 0 hour. As listed under the field of 3000 hours in Table 2, Comparative Example 1 showed an open-circuit voltage (Voc) of 1.36 V, a short-circuit current density (Jsc) of 13.7 mA/cm², a fill factor (F. F.) of 66.8%, and conversion efficiency (Eff) of 12.5%, as output characteristics after 3000 hours, particularly showing significant decrease in fill factor (F. F.) as compared with Example 1.

### Example 2

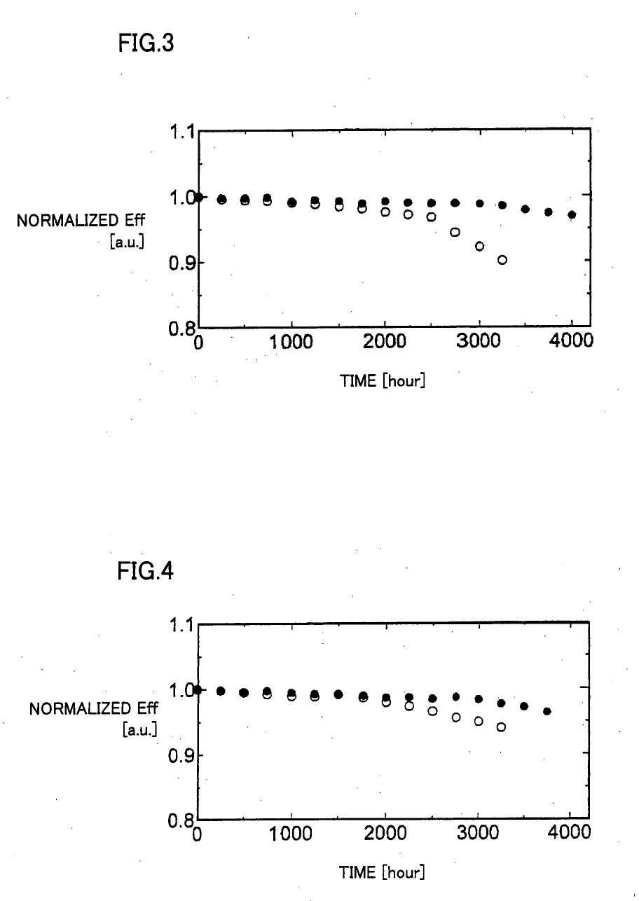

A double junction type of thin film silicon-based photoelectric converter was formed differently from Example 1 only in that intermediate reflective layer 4a was omitted and the crystalline silicon photoelectric conversion layer was made in 1.5 μm thickness. Its output characteristics were measured and the reliability tests were performed thereon in the same manner as in Example 1. As listed under the field of 0 hour in Table 2, Example 2 showed an open-circuit voltage (Voc) of 1.39 V, a short-circuit current density (Jsc) of 11.7 mA/cm², a fill factor (F. F.) of 73.4%, and conversion efficiency (Eff) of 11.9%, as output characteristics. The results of the reliability tests are shown by black dots in FIG. 3. As listed under the filed of 3000 hours in Table 2, Example 2 showed an open-circuit voltage (Voc) of 1.39 V, a short-circuit current density (Jsc) of 11.7 mA/cm², a fill factor (F. F.) of 72.2%, and conversion efficiency (Eff) of 11.8%, as output characteristics after 3000 hours. It is note that FIG. 3 shows the conversion efficiency (Eff) normalized with respect to the Eff at 0 hour.

### Comparative Example 2

A double junction type of thin film silicon-based photoelectric converter was formed differently from Example 2 only in that back reflective layer 4b was formed under condition B of Table 1. Its output characteristics were measured in the same manner as in Example 2, and the reliability tests were performed thereon concurrently with the test on Example 2. As listed under the field of 0 hour in Table 2, Comparative Example 2 showed an open-circuit voltage (Voc) of 1.40 V, a short-circuit current density (Jsc) of 11.6 mA/cm², a fill factor (F. F.) of 74.3%, and conversion efficiency (Eff) of 12.0%, as output characteristics. The results of the reliability tests are shown by white dots in FIG. 3, showing that the conversion efficiency (Eff) was deteriorated earlier as compared to Example 2. It is noted that, similarly as in the case of the black dots, the white dots also show the conversion efficiency (Eff) normalized with respect to the Eff at 0 hour. As listed in the field of 3000 hours in Table 2, Comparative Example 2 showed an open-circuit voltage (Voc) of 1.39 V, a short-circuit current density (Jsc) of 11.7 mA/cm², a fill factor (F. F.) of 68.3%, and conversion efficiency (Eff) of 11.1%, as output characteristics after 3000 hours, indicating significant decrease in fill factor as compared to Example 2.

### Example 3

A double junction type of thin film silicon-based photoelectric converter was formed differently from Example 1 only in that it had no back reflective layer 4b. Its output characteristics were measured and the reliability tests were performed thereon in the same manner as in Example 1. As listed under the field of 0 hour in Table 2, Example 3 showed an open-circuit voltage (Voc) of 1.38 V, a short-circuit current density (Jsc) of 12.8 mA/cm², a fill factor (F. F.) of 74.3%, and conversion efficiency (Eff) of 13.1%, as output characteristics. The results of the reliability tests are shown by black dots in FIG. 4. As listed under the field of 3000 hours in Table 2, Example 3 showed an open-circuit voltage (Voc) of 1.37 V, a short-circuit current density (Jsc) of 12.8 mA/cm², a fill factor (F. F.) of 73.5%, and conversion efficiency (Eff) of 12.9%, as output characteristics after 3000 hours. It is noted that FIG. 4 shows the conversion efficiency (Eff) normalized with respect to the Eff at 0 hour.

### Comparative Example 3

A double junction type of thin film silicon-based photoelectric converter was formed differently form Example 3 only in that intermediate reflective layer 4a was formed under condition B of Table 1. Its output characteristics were measured in the same manner as in Example 3, and the reliability tests were performed thereon concurrently with the test on Example 3. As listed in the field of 0 hour in Table 2, Comparative Example 3 showed an open-circuit voltage (Voc) of 1.38 V, a short-circuit current density (Jsc) of 12.9 mA/cm², a fill factor (F. F.) of 74.4%, and conversion efficiency (Eff) of 13.2%, as output characteristics. The results of the reliability tests are shown by white dots in FIG. 4, showing that the conversion efficiency (Eff) deteriorated earlier as compared to Example 3. It is noted that, similarly as in the case of the black dots, the white dots also indicate the conversion efficiency (Eff) normalized with respect to the Eff at 0 hour. As listed in the field of 3000 hours in Table 2, Comparative Example 3 showed an open-circuit voltage (Voc) of 1.38 V, a short-circuit current density (Jsc) of 12.9 mA/cm², a fill factor (F. F.) of 70.2%, and conversion efficiency (Eff) of 12.6%, as output characteristics after 3000 hours, indicating significant decrease in fill factor (F. F.) as compared to Example 3.

1. A photoelectric converter comprising at least one thin film silicon-based photoelectric conversion unit mainly composed of a silicon-based thin film containing at least one semiconductor junction, and a silicon alloy layer containing a kind of dopant for determining a conductivity type, oxygen, nitrogen, and crystalline silicon on a side opposite to a light incident side of the photoelectric conversion unit, wherein the silicon alloy layer has a refractive index of at most 2.5 and a nitrogen concentration in a range of 1×10²¹ atoms/cc to 1×10²² atoms/cc.
